(19) United States
(12) Patent Application Publication
(10) Pub. No.: US 2026/0313904 A1
(43) Pub. Date: Oct. 8, 2026

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventors: Seok Hyun LEE, Gyeonggi-do (KR); Hyo Sub YEOM, Gyeonggi-do (KR)

(21) Appl. No.: 19/260,630

(22) Filed: Jul. 7, 2025

(30) Foreign Application Priority Data
Apr. 3, 2025 (KR) 10-2025-0043565

(51) Int. Cl. H10B 43/50; H10B 41/27; H10B 41/50; H10B 43/27

(52) U.S. Cl. CPC H10B 43/50; H10B 41/27; H10B 41/50; H10B 43/27

(57) ABSTRACT

A semiconductor device includes: a gate structure disposed in a chip region and including alternately stacked conductive layers and first insulating layers ; a dummy structure, disposed in a chip guard region surrounding the chip region, including alternately stacked second insulating layers and third insulating layers; and a chip guard structure, located in the chip guard region, including a polysilicon layer disposed in the dummy structure and a conductive line surrounding the polysilicon layer and extending through the dummy structure.

### CROSS-REFERENCE TO RELATED APPLICATION

This application claims priority under 35 U.S.C. § 119 to Korean Patent Application No. 10-2025-0043565 filed on Apr. 3, 2025, which is incorporated herein by reference in its entirety.

### BACKGROUND

### 1. Technical Field

Embodiments of the present disclosure relate to an electronic device, and more particularly, to a semiconductor device and a method of manufacturing the semiconductor device.

### 2. Related Art

The degree of integration of a semiconductor device is mainly determined by an area occupied by a unit memory cell. Recently, as the improvement in the degree of integration of semiconductor devices that are used for forming memory cells in a single layer on a substrate reaches a limit, three-dimensional semiconductor devices for stacking memory cells on a substrate have been proposed. Furthermore, various structures and manufacturing methods have been developed to improve the operational reliability of such a semiconductor device.

### SUMMARY

In an embodiment, a semiconductor device may include: a gate structure disposed in a chip region and including alternately stacked conductive layers and first insulating layers; a dummy structure, disposed in a chip guard region surrounding the chip region, including alternately stacked second insulating layers and third insulating layers; and a chip guard structure, located in the chip guard region, including a polysilicon layer disposed in the dummy structure and a conductive line surrounding the polysilicon layer and extending through the dummy structure.

In an embodiment, a semiconductor device may include: a dummy structure including alternately stacked first insulating layers and second insulating layers; a stop layer including a first sub stop layer located in the dummy structure and a second sub stop layer surrounding the first sub stop layer; a buffer layer surrounding the stop layer; and a conductive line surrounding the buffer layer and having a closed curve shape extending through the dummy structure.

In an embodiment, a method of manufacturing a semiconductor device may include: forming a stack in a chip region and a chip guard region surrounding the chip region, the stack including alternately stacked first material layers and second material layers; forming a trench in the chip guard region of the stack, the trench surrounding the chip region; forming a buffer layer in the trench, the buffer layer including a void; and forming a slit in the buffer layer, the slit being connected to the void to define an air gap within the void and the slit, wherein the air gap is configured to stop propagation of a crack from the chip region toward the chip guard region.

In an embodiment, a method of manufacturing a semiconductor device may include: forming a stack in a chip region and a chip guard region surrounding the chip region, the stack including alternately stacked first material layers and second material layers; forming a trench in the chip guard region of the stack, the trench surrounding the chip region; forming a buffer layer in the trench, the buffer layer including a void; forming a slit in the buffer layer, the slit being connected to the void; and forming a stop layer in the void and the slit, wherein the stop layer is configured to stop propagation of a crack from the chip region toward the chip guard region.

### BRIEF DESCRIPTION OF THE DRAWINGS

The above and other objects, features and advantages of the present disclosure will be more apparent from the following detailed description taken in conjunction with the accompanying drawings:

FIGS. 1A and 1B are diagrams illustrating the structure of a semiconductor device in accordance with an embodiment of the present disclosure.

FIGS. 2A to 2C are diagrams illustrating the structure of a semiconductor device in accordance with an embodiment of the present disclosure.

FIGS. 3A to 3C are diagrams illustrating the structure of a semiconductor device in accordance with an embodiment of the present disclosure.

FIG. 4 is a diagram illustrating the structure of a semiconductor device in accordance with an embodiment of the present disclosure.

FIG. 5 is a diagram illustrating a cross-sectional view of the structure of a semiconductor device, including the structures of a chip region and a chip guard region in accordance with an embodiment of the present disclosure.

FIG. 6 is a diagram illustrating the structure of a semiconductor device in accordance with an embodiment of the present disclosure.

FIGS. 7A, 8A, 9A, 10A, and 11A, FIGS. 7B, 8B, 9B, 10B, and 11B, and FIGS. 7C, 8C, 9C, 10C, and 11C are diagrams for describing a method of manufacturing a semiconductor device in accordance with an embodiment of the present disclosure.

FIGS. 12A, 13A, and 14A and FIGS. 12B, 13B, and 14B are diagrams for describing a method of manufacturing a semiconductor device in accordance with an embodiment of the present disclosure.

FIGS. 15A, 16A, 17A, 18A, 19A, 20A, 21A, 22A, 23A, 24A, and 25A and FIGS. 15B, 16B, 17B, 18B, 19B, 20B, 21B, 22B, 23B, 24B, and 25B are diagrams for describing a method of manufacturing a semiconductor device in accordance with an embodiment of the present disclosure.

FIGS. 26A to 26D are diagrams for describing a method of manufacturing a semiconductor device in accordance with an embodiment of the present disclosure.

FIG. 27 is a configuration diagram of a semiconductor device in accordance with an embodiment of the present disclosure.

FIG. 28 is a configuration diagram of a semiconductor device in accordance with an embodiment of the present disclosure.

### DETAILED DESCRIPTION

Various embodiments are directed to a semiconductor device having a stable structure and improved characteristics and a method of manufacturing the semiconductor device.

Hereinafter, various embodiments of the present disclosure are described with reference to accompanying drawings. Advantages and features of the present disclosure and methods for implementing them will become apparent with reference to embodiments to be described below in detail together with the accompanying drawings. However, this is not intended to limit the present disclosure to specific embodiments.

The present disclosure may be implemented in various different forms without being limited to an embodiment and should be understood as including various modifications, equivalents, and/or alternatives of embodiments of the present disclosure.

Also, in adding reference numerals to components of each drawing, it should be noted that like components are designated by like numerals even though illustrated on other drawings.

In the specification, the singular forms include plural forms unless otherwise mentioned. The terms “comprises” and/or “comprising”, which are used in the specification, specify the presence of components, steps, operations, and/or elements, but do not preclude the presence or addition of one or more other components, steps, operations, and/or elements.

Herein below, by stacking memory cells in three dimensions, embodiments of the present disclosure provide a capability to improve the degree of integration of a semiconductor device. The embodiments of the present disclosure also provide a semiconductor device having a stable structure and improved reliability.

Hereafter, embodiments in accordance with the technical spirit of the present disclosure will be described with reference to the accompanying drawings.

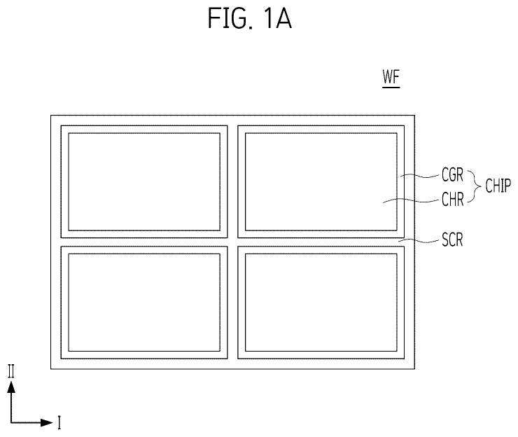

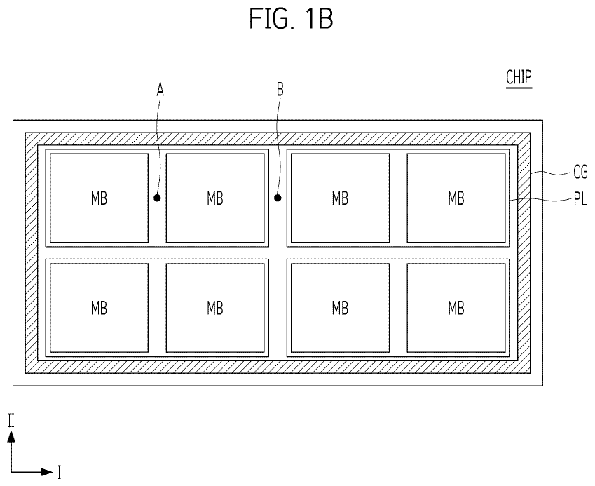

FIGS. 1A and 1B are diagrams illustrating the structure of a semiconductor device in accordance with an embodiment of the present disclosure.

Referring to FIG. 1A, the semiconductor device may include a wafer WF, and the wafer WF may include chips CHIP and a scribe lane region SCR. The chips CHIP may be arranged in a first direction I and a second direction II intersecting the first direction I. The scribe lane region SCR may be located between the chips CHIP, and may surround the chips CHIP. The scribe lane region SCR may be a portion diced by a dicing process for separating the chips CHIP from each other.

The chip CHIP may include a chip region CHR and a chip guard region CGR surrounding the chip region CHR. The chip region CHR is a region where an element operating in the chip CHIP is formed. The chip guard region CGR is a region for protecting the element, and may be a region where the element is not formed or a dummy element is formed. When the dicing process is performed, the chip region CHR may be protected by the chip guard region CGR.

Referring to FIG. 1B, the chip CHIP may include a plurality of memory planes PL arranged in the first direction I and the second direction II. As an example, the memory planes PL may be arranged in a matrix form in the chip region CHR. The memory plane PL may include a plurality of memory blocks MB, and the memory block MB may be a unit of an erase operation. As an example, the memory plane PL may include two or more memory blocks MB arranged in the first direction I.

A chip guard structure CG may be located at an edge of the chip CHIP. An inner region of the chip guard structure CG may be the chip region CHR, and an outer region of the chip guard structure CG may be the chip guard region CGR. The chip guard structure CG may extend along the edge of the chip CHIP, and may have a closed curve shape. As an example, the chip guard structure CG may have a rectangular shape. Because the chip guard structure CG has a shape in which it surrounds the chip region CHR, the propagation of a crack may be stopped and the crack may be detected, using the chip guard structure CG.

The crack(s) may be induced in a manufacturing process of a semiconductor device. Stress may be induced due to a void, shrinkage of a layer, and the like, induced in the manufacturing process, and a defect(s) such as poor oxidation and the crack may occur due to the stress. The crack may be induced at an interface between an interlayer insulating layer and a stack, and may propagate in one direction along the interface. As an example, the crack is likely to occur and propagate at the interface between the interlayer insulating layer and the stack located at a boundary A between the memory blocks MB or a boundary B between the memory planes PL. The crack may propagate from the inside of the chip CHIP to the outside of the chip CHIP or propagate between adjacent chips CHIP. Accordingly, by stopping the propagation of the crack using the chip guard structure CG, the disclosed embodiments may reduce the propagation of the crack between the chips CHIP.

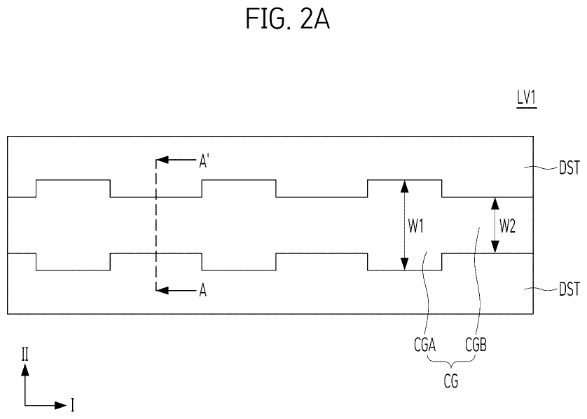

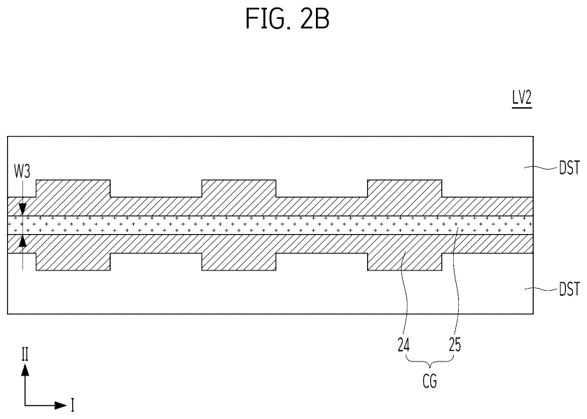

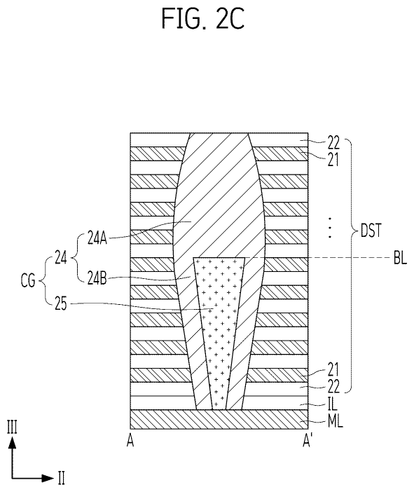

FIGS. 2A to 2C are diagrams illustrating the structure of a semiconductor device in accordance with an embodiment. FIGS. 2A and 2B are plan views, and FIG. 2C is a cross-sectional view taken along line A-A′ of FIG. 2A. Hereinafter, the content overlapping with the previously described content may be omitted.

Referring to FIG. 2A, the semiconductor device may include a dummy structure DST and a chip guard structure CG. The dummy structure DST may be located in a chip guard region CGR. The dummy structure DST may include first insulating layers 21 and second insulating layers 22 that are alternately stacked (as shown in FIG. 2C). The first insulating layers 21 may each include a material having a high etching selectivity with respect to the second insulating layers 22. As an example, the first insulating layers 21 may each include nitride, and the second insulating layers 22 may each include oxide.

The chip guard structure CG may be located in the chip guard region CGR. As an example, the chip guard structure CG may be located at a boundary between a chip region CHR and the chip guard region CGR. The chip guard structure CG may have a line shape or have a closed curve shape such as a quadrangular shape. In a plane defined by the first direction I and the second direction II intersecting the first direction I, the chip guard structure CG may extend in the first direction I and/or the second direction II through the dummy structure DST. The chip guard structure CG may include a first portion CGA having a first width W1 and a second portion CGB having a second width W2. The first width W1 and the second width W2 may be different from each other, and the first width W1 may be greater than the second width W2. The chip guard structure CG may include first portions CGA and second portions CGB that are alternately arranged. The chip guard structure CG may include sidewalls having an irregular shape.

Referring to FIGS. 2B and 2C, the semiconductor device may include a dummy structure DST and a chip guard structure CG, and may further include a wiring line ML and an interlayer insulating layer IL. The chip guard structure CG may include a conductive line 24 and a stop layer 25. The stop layer 25 may be located inside the conductive line 24. In a plan view, the stop layer 25 may be located in a partial region of the conductive line 24. As an example, the stop layer 25 may be located in a region where cracks frequently (or are most likely to) occur. The stop layer 25 may be located at a boundary between memory blocks or a boundary between memory planes, and might not be located in other regions. In a plan view, the stop layer 25 may be located in an entire region of the conductive line 24. As an example, the stop layer 25 may be located along an edge of a chip CHIP.

The conductive line 24 may be a portion of a crack detection circuit, and may be used as a detection line for detecting the crack. In addition, the propagation of the crack may be stopped by the conductive line 24. The conductive line 24 may include a conductive material having a higher density and/or elastic modulus (Young's modulus) than silicon oxide. As an example, the conductive line 24 may include metal such as tungsten (W), copper (Cu), or aluminum (Al). The stop layer 25 is used to stop the propagation of the crack, and may include a material having a higher density and/or elastic modulus (Young's modulus) than silicon oxide. As an example, the stop layer 25 may include silicon nitride, polysilicon, or the like.

In a plan view, the conductive line 24 may extend in the first direction I and/or the second direction II through the dummy structure DST, and the stop layer 25 may extend in the first direction I or the second direction II through the conductive line 24.

In a cross section, the conductive line 24 may extend in a third direction III through the dummy structure DST. As an example, the conductive line 24 may penetrate through the dummy structure DST, and may be electrically connected to the wiring line ML located below the dummy structure DST. The conductive line 24 may have a cross section with a bow shape. As an example, the conductive line 24 may have a smaller width in a lower surface thereof than an upper surface thereof, and may have a maximum width at a bowing level BL between the upper surface and the lower surface. In a cross section, the stop layer 25 may be located only at a partial level of the conductive line 24. An upper surface of the stop layer 25 may be located lower than the upper surface of the conductive line 24. As an example, the stop layer 25 may be located from the lower surface of the conductive line 24 to the bowing level BL. Alternatively, the stop layer 25 may be located from the lower surface of the conductive line 24 to a level above or below the bowing level BL, but below the upper surface of the conductive line 24. The stop layer 25 may include polysilicon, silicon nitride, or the like.

The conductive line 24 may surround the upper surface and sidewalls of the stop layer 25. The conductive line 24 may include a first portion 24A located on an upper portion of the stop layer 25 and a second portion 24B surrounding the sidewalls of the stop layer 25. The second portion 24B may protrude from a lower surface of the first portion 24A, and may extend along the sidewalls of the stop layer 25. Because the conductive line 24 surrounds the upper surface and the sidewalls of the stop layer 25, the stop layer 25 may be separated from the dummy structure DST.

According to the structure described above, because the chip guard structure CG includes the stop layer 25, the propagation of the crack may be stopped using the chip guard structure CG. Because the chip guard structure CG includes the conductive line 24 having a closed curve shape, the chip guard structure CG may be used as the detection line of the crack detection circuit.

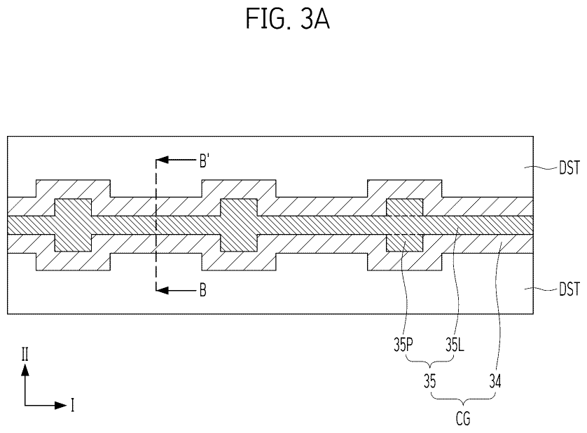

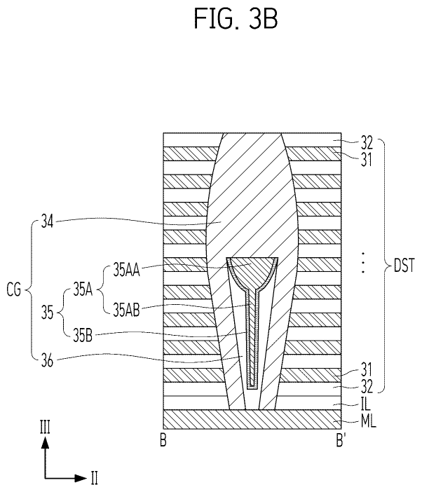

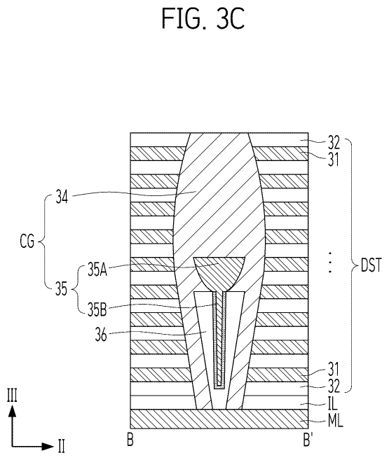

FIGS. 3A to 3C are diagrams illustrating the structure of a semiconductor device in accordance with an embodiment of the present disclosure. FIG. 3A is a plan view, and FIGS. 3B and 3C are cross-sectional views taken along line B-B′ of FIG. 3A. Hereinafter, the content overlapping with the previously described content may be omitted.

Referring to FIGS. 3A to 3C, the semiconductor device may include a dummy structure DST and a chip guard structure CG. The dummy structure DST may include first insulating layers 31 and second insulating layers 32 that are alternately stacked. In a plan view, the chip guard structure CG may extend in the first direction I through the dummy structure DST. In a cross section, the chip guard structure CG may extend in the third direction III through the dummy structure DST, and may be electrically connected to a wiring line ML.

The chip guard structure CG may include a conductive line 34 and a stop layer 35 located in the conductive line 34. In a plan view, the stop layer 35 may include a line portion 35L and at least one protrusion portion 35P. As an example, the stop layer 35 may have sidewalls with an irregular shape. The line portion 35L may extend in the first direction I through the conductive line 34. The protrusion portion 35P may protrude in the second direction II from the line portion 35L. The protrusion portion 35P may be located to correspond to the first portion CGA of the chip guard structure CG. The chip guard structure CG may further include a buffer layer 36 surrounding the stop layer 35.

The stop layer 35 may include a first stop layer 35A (for example, a first sub stop layer) and a second stop layer 35B (for example, a second sub stop layer). The second stop layer 35B may surround the first stop layer 35A, and the buffer layer 36 may surround the second stop layer 35B. The first stop layer 35A may include a semiconductor layer or a conductive layer, and may include a material having a higher density and/or elastic modulus (Young's modulus) than the second stop layer 35B and the buffer layer 36. The second stop layer 35B and the buffer layer 36 may each include a dielectric material, and the second stop layer 35B may include a material having a higher density and/or elastic modulus (Young's modulus) than the buffer layer 36. As an example, the first stop layer 35A may include polysilicon, the second stop layer 35B may include oxide or nitride, and the buffer layer 36 may include oxide. For reference, when both the second stop layer 35B and the buffer layer 36 include oxide, an interface between the second stop layer 35B and the buffer layer 36 might not be confirmed.

In a cross section, the first stop layer 35A may include a first portion 35AA and a second portion 35AB. The first portion 35AA may be a portion filling a void induced in a manufacturing process, and may include a curved surface. The second portion 35AB may be a portion filling a slit formed in the manufacturing process, and may have a smaller width than the first portion 35AA.

Upper surfaces of the first stop layer 35A, the second stop layer 35B, and the buffer layer 36 may be located at substantially the same level or different levels. In the example of FIG. 3B, the upper surfaces of the first stop layer 35A, the second stop layer 35B, and the buffer layer 36 may be located at substantially the same level. In the example of FIG. 3C, the upper surfaces of the first stop layer 35A, the second stop layer 35B, and the buffer layer 36 may be located at different levels. A level difference between the upper surfaces may be due to a difference between etch rates. The upper surfaces of the second stop layer 35B and the buffer layer 36 may be located at a lower level than the upper surface of the first stop layer 35A. As an example, the first portion 35AA of the first stop layer 35A may protrude from the upper surfaces of the second stop layer 35B and the buffer layer 36. The upper surface of the second stop layer 35B and the upper surface of the buffer layer 36 may be located at substantially the same level or at different levels.

According to the structure described above, the chip guard structure CG may include the conductive line 34, the stop layer 35, and the buffer layer 36, and the stop layer 35 may have a multilayer structure. By forming the stop layer 35 by combining material layers having various densities and/or elastic moduli with each other, the disclosed embodiments provide a capability to stop the propagation of cracks in the semiconductor device.

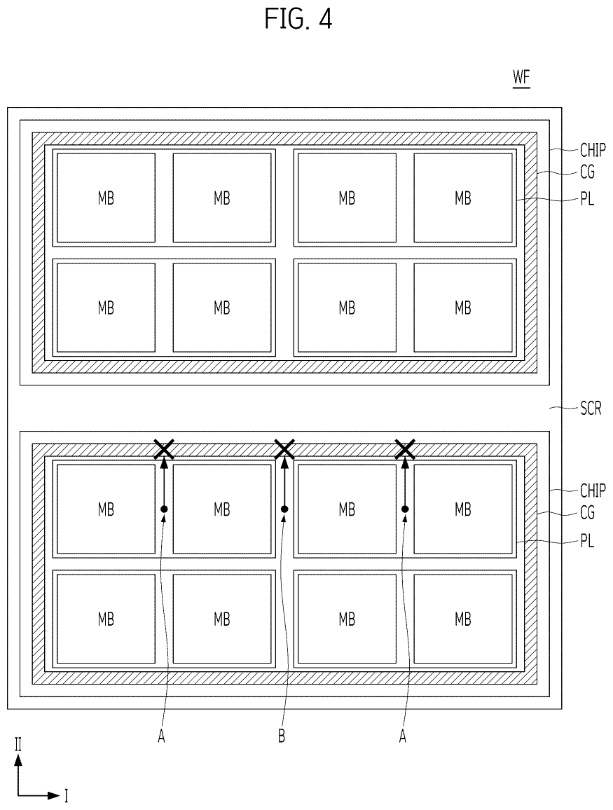

FIG. 4 is a diagram illustrating the structure of a semiconductor device in accordance with an embodiment. Hereinafter, the content overlapping with the previously described content may be omitted.

Referring to FIG. 4, the semiconductor device may include a wafer WF, and the wafer WF may include chips CHIP and a scribe lane region SCR. The chip CHIP may include memory planes PL located in a chip region CHR as shown in FIG. 1A, and may include a chip guard structure CG located in a chip guard region CGR as shown in FIG. 1A. As an example, the chip guard structure CG may be located at a boundary between the chip region CHR and the chip guard region CGR.

A crack may occur due to an oxidation process or the like in a manufacturing process of the semiconductor device, and the crack occurring in the chip region CHR may propagate toward the chip guard region CGR. The crack may propagate to the scribe lane region SCR through the chip guard region CGR, and may propagate to an adjacent chip CHIP. As an example, the crack may occur at a boundary A between memory blocks MB or at a boundary B between adjacent memory planes PL. The crack may be induced at an interface between a stack of the boundary (region) A and/or the boundary (region) B and an interlayer insulating layer, and may propagate in one direction along the interface.

Accordingly, in order to stop the propagation of the crack, the chip guard structure CG including a stop layer may be disposed (for example, located) at an edge of the chip CHIP. The stop layer may be located only in a partial region of the edge of the chip CHIP. As an example, the stop layer may be located only in a portion of the edge of the chip CHIP extending and reached from the A region A and/or the B region B along the second direction II. In alternative embodiments, the stop layer may be entirely located at the edge of the chip CHIP.

According to the structure described above, even in instances in which cracks occur in the manufacturing process, the propagation of these cracks may be stopped by the chip guard structure CG. Accordingly, the crack may not propagate to adjacent chips CHIP.

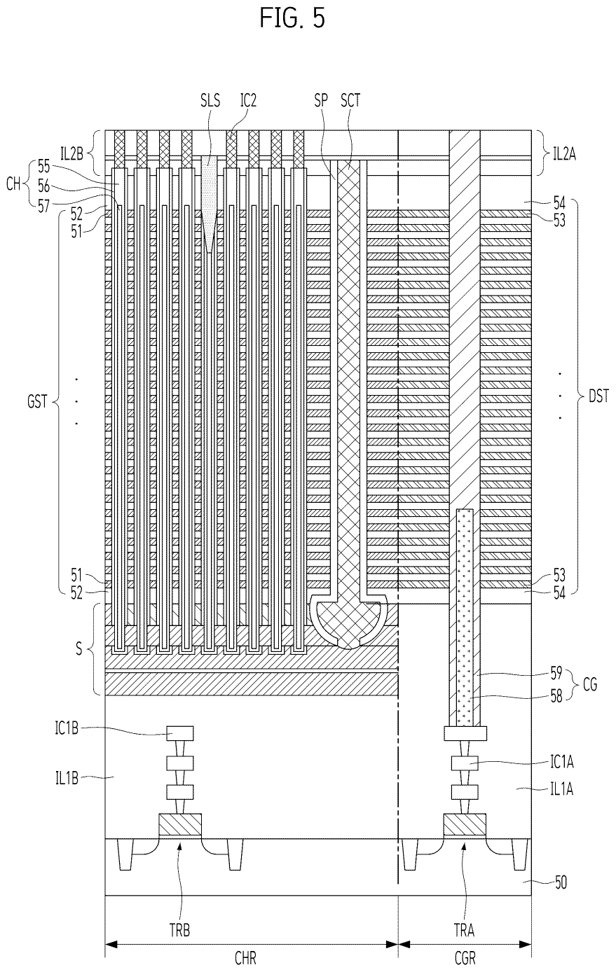

FIG. 5 is a diagram illustrating a cross-sectional view of the structure of a semiconductor device, including the structures of a chip region CHR and a chip guard region CGR in accordance with an embodiment of the present disclosure. Hereinafter, the content overlapping with the previously described content may be omitted.

Referring to FIG. 5, the semiconductor device may include a substrate 50, a gate structure GST, a channel structure CH, a source structure S, a slit structure SLS, a dummy structure DST, a first transistor TRA, a second transistor TRB, a chip guard structure CG, first interlayer insulating layers IL1A and IL1B, second interlayer insulating layers IL2A and IL2B, first interconnection structures IC1A and IC1B, and a second interconnection structure IC2.

The second transistor TRB may be located in the chip region CHR of the substrate 50. The second transistor TRB may belong to a peripheral circuit for driving a memory cell array. The peripheral circuit may include a page buffer, a row decoder, a logic circuit, an input/output circuit, and the like. The first interconnection structure IC1B may include a via, a wiring line, and the like, and may be located in the first interlayer insulating layer IL1B. The first interconnection structure IC1B may be connected to the second transistor TRB.

In the chip region CHR, the source structure S may be located on the first interlayer insulating layer IL1B. The source structure S may be composed of a single layer or a multilayer layer. The source structure S may include a conductive material such as polysilicon or metal.

The gate structure GST may be located on the source structure S. The gate structure GST may include conductive layers 51 and insulating layers 52 that are alternately stacked. The conductive layers 51 may be gate lines such as a drain select line, a source select line, and word lines. The conductive layers 51 may each include a conductive material such as polysilicon or metal. The insulating layers 52 are used to insulate the stacked conductive layers 51 from each other, and may each include an insulating material such as oxide, nitride, or air gap.

The channel structure CH may extend into the source structure S through the gate structure GST. The channel structure CH may include a channel layer 55, a memory layer 56, and an insulating core 57. The channel layer 55 may be connected to the source structure S. The memory layer 56 may include at least one of a tunneling layer, a data storage layer, and a blocking layer. The data storage layer may include a floating gate, polysilicon, a charge trap material, nitride, a variable resistance material, or the like.

A source contact plug SCT may extend into the source structure S through the gate structure GST. The source contact plug SCT may be electrically connected to the source structure S. An insulating spacer SP may surround sidewalls of the source contact plug SCT. The slit structure SLS may extend through the gate structure GST. As an example, the slit structure SLS may have a depth enough to penetrate through the conductive layers 51 corresponding to the drain select lines. The slit structure SLS may include an insulating material such as oxide or nitride.

The second interlayer insulating layer IL2B may be located on the gate structure GST, and the second interconnection structure IC2 may be located in the second interlayer insulating layer IL2B. The second interconnection structure IC2 may be connected to the channel structure CH, the gate structure GST, and the like, and may include a via, a wiring line, and the like.

The first transistor TRA may be located in the chip guard region CGR of the substrate 50. The first transistor TRA may belong to a crack detection circuit. The first interconnection structure IC1A may include a via, a wiring line, and the like, and may be located in the first interlayer insulating layer IL1A. The first interconnection structure IC1A may be connected to the first transistor TRA.

In the chip guard region CGR, the dummy structure DST may be located on the first interlayer insulating layer IL1A. The dummy structure DST may be located at a level corresponding to the gate structure GST. The dummy structure DST may include first insulating layers 53 and second insulating layers 54 that are alternately stacked. The second insulating layers 54 may be connected to the insulating layers 52 as single layers. The second interlayer insulating layer IL2A may be located on the dummy structure DST.

The chip guard structure CG may extend through the dummy structure DST, and may be connected to the first interconnection structure IC1A. The chip guard structure CG may include a conductive line 59 and a stop layer 58 located in the conductive line 59. The stop layer 58 may include a semiconductor material, a conductive material, a dielectric material, or the like. The chip guard structure CG, the first interconnection structure IC1A connected to the chip guard structure CG, and the first transistor TRA may be a portion of the crack detection circuit. Because a chip crack mainly occurs at an outer portion of a chip, the chip guard structure CG may be formed in the form of a closed loop circuit extending along the outer portion of the chip. A current may be applied to the closed loop circuit, and the crack may be detected based on whether (or not) the current flows through the closed loop circuit.

According to the structure described above, by locating the peripheral circuit below the memory cell array, the disclosed embodiments enable an increase in the degree of integration of the semiconductor device. The crack may be detected using the crack detection circuit including the chip guard structure CG, and the propagation of the crack may be stopped using the chip guard structure CG.

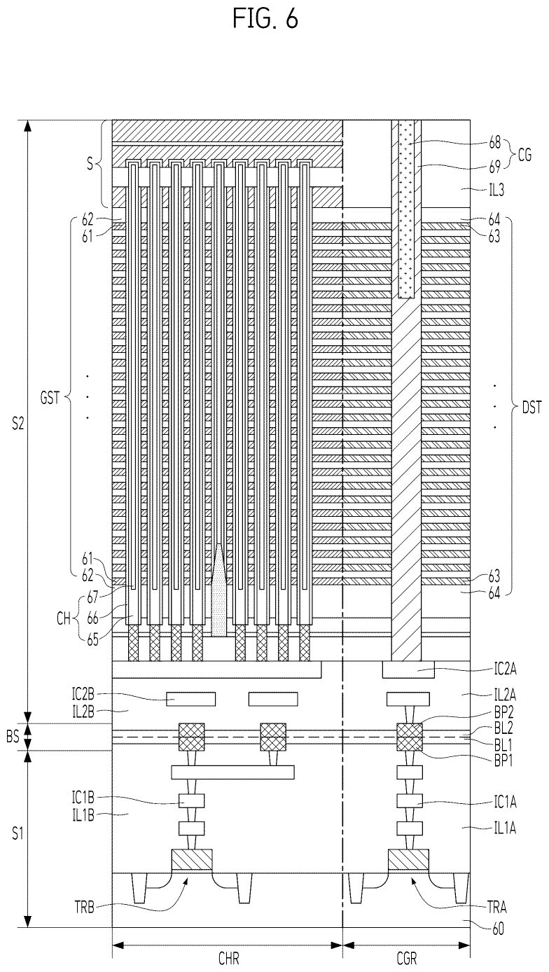

FIG. 6 is a diagram illustrating the structure of a semiconductor device in accordance with an embodiment. Hereinafter, the content overlapping with the previously described content may be omitted.

Referring to FIG. 6, the semiconductor device may include a first semiconductor structure S1, a second semiconductor structure S2, and a bonding structure BS located between the first semiconductor structure S1 and the second semiconductor structure S2. The first semiconductor structure S1 and the second semiconductor structure S2 may be formed by separate processes, and may be electrically connected to each other by the bonding structure BS. As an example, the first semiconductor structure S1 may include a peripheral circuit and a crack detection circuit, and the second semiconductor structure S2 may include a memory cell array.

The first semiconductor structure S1 may include a chip region CHR and a chip guard region CGR, and may include a substrate 60, a first transistor TRA, a second transistor TRB, first interconnection structures IC1A and IC1B, and first interlayer insulating layers IL1A and IL1B.

The second transistor TRB may be located in the chip region CHR of the substrate 60. The second transistor TRB may belong to a peripheral circuit for driving a memory cell array. The first interconnection structure IC1B may include a via, a wiring line, and the like, and may be located in the first interlayer insulating layer IL1B. The first interconnection structure IC1B may be connected to the second transistor TRB.

The first transistor TRA may be located in the chip guard region CGR of the substrate 60. The first transistor TRA may belong to the crack detection circuit. The first interconnection structure IC1A may include a via, a wiring line, and the like, and may be located in the first interlayer insulating layer IL1A. The first interconnection structure IC1A may be connected to the first transistor TRA. The first transistor TRA and the first interconnection structure IC1B connected to the first transistor TRA may be a portion of the crack detection circuit.

The second semiconductor structure S2 may include a source structure S, a gate structure GST, a dummy structure DST, a chip guard structure CG, second interconnection structures IC2A and IC2B, second interlayer insulating layers IL2A and IL2B, and a third interlayer insulating layer IL3.

The source structure S, the gate structure GST, and a channel structure CH may be located in the chip region CHR. The source structure S may be located above or below the gate structure GST. The source structure S may include a conductive material such as polysilicon or metal. The gate structure GST may include conductive layers 61 and insulating layers 62 that are alternately stacked. The conductive layers 61 may be gate lines such as a source select line, a drain select line, and word lines. The channel structure CH may extend through the gate structure GST, and may be connected to the source structure S. The channel structure CH may include a channel layer 65, a memory layer 66, and an insulating core 67.

The second interconnection structure IC2B may be located in the second interlayer insulating layer IL2B, and may include a via, a wiring line, and the like. The second interconnection structure IC2B may be connected to the channel structure CH, the gate structure GST, and the like.

The dummy structure DST and the chip guard structure CG may be located in the chip guard region CGR. The dummy structure DST may be located at a level corresponding to the gate structure GST. The dummy structure DST may include first insulating layers 63 and second insulating layers 64 that are alternately stacked. The second insulating layers 64 may be connected to the insulating layers 62 as single layers. The second interlayer insulating layer IL2A may be located below the dummy structure DST. The third interlayer insulating layer IL3 may be located above the dummy structure DST.

The chip guard structure CG may extend through the dummy structure DST, and may be connected to the second interconnection structure IC2A. The chip guard structure CG may include a conductive line 69 and a stop layer 68 located in the conductive line 69. The stop layer 68 may include a semiconductor material, a conductive material, a dielectric material, or the like. The chip guard structure CG and the second interconnection structure IC2A connected to the chip guard structure CG may be a portion of the crack detection circuit.

The bonding structure BS may include a first bonding layer BL1, a second bonding layer BL2, first bonding pads BP1, and second bonding pads BP2. The first bonding layer BL1 and the second bonding layer BL2 may be in contact with each other. The first bonding pad BP1 and the second bonding pad BP2 may be in contact with each other. The first bonding layer BL1 and the second bonding layer BL2 may each include Silicon Carbonitride (SiCN), tetra ethyl ortho silicate (TEOS), or the like. The first bonding pads BP1 may be electrically connected to the first interconnection structures IC1A and IC1B. The second bonding pads BP2 may be electrically connected to the second interconnection structures IC2A and IC2B. The memory cell array and the peripheral circuit may be electrically connected to each other through the first bonding pad BP1 and the second bonding pad BP2.

According to the structure described above, the chip guard structure CG and the first transistor TRA may be connected to each other through the bonding structure BS. A crack may be detected using the crack detection circuit including the chip guard structure CG, and the propagation of the crack may be stopped using the chip guard structure CG.

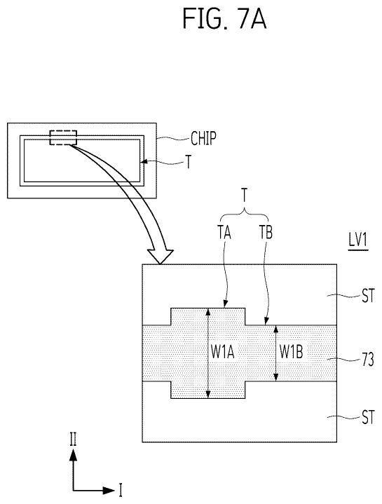

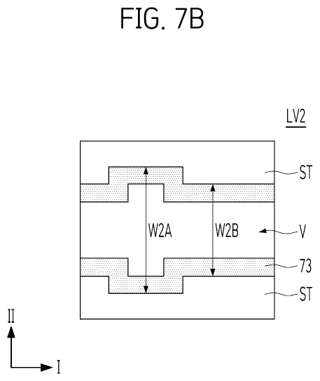

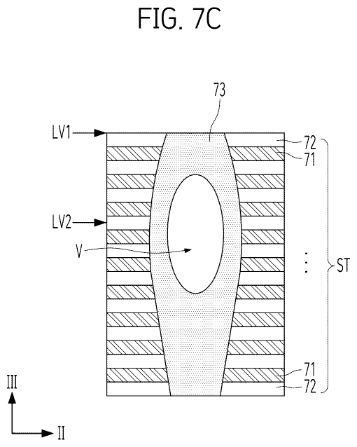

FIGS. 7A, 8A, 9A, 10A, and 11A, FIGS. 7B, 8B, 9B, 10B, and 11B, and FIGS. 7C, 8C, 9C, 10C, and 11C are diagrams for describing a method of manufacturing a semiconductor device in accordance with an embodiment of the present disclosure. FIGS. 7A, 8A, 9A, 10A, and 11A are plan views of FIGS. 7C, 8C, 9C, 10C, and 11C at a first level LV1, and FIGS. 7B, 8B, 9B, 10B, and 11B are plan views of FIGS. 7C, 8C, 9C, 10C, and 11C at a second level LV2.

Referring to FIGS. 7A to 7C, a stack ST including first material layers 71 and second material layers 72 that are alternately stacked may be formed. The first material layers 71 may each include a material having a high etching selectivity with respect to the second material layers 72. As an example, the first material layers 71 may each include nitride, and the second material layers 72 may each include oxide.

Subsequently, a trench T may be formed in the stack ST. In a plan view, the trench T may extend in the first direction I and/or the second direction II through the stack ST. As an example, the trench T may have a closed curve shape. The trench T may include a first portion TA having a first width W1A and a second portion TB having a second width W1B. The first width W1A and the second width W1B may be substantially the same as or different from each other. When the first width W1A and the second width W1B are substantially the same as each other, the trench T may have a line shape. When the first width W1A and the second width W1B are different from each other, the trench T may have an irregular shape. As an example, the first width W1A may be greater than the second width W1B.

In a cross section, the trench T may extend in the third direction III through the stack ST, and may have a bow shape. In the third direction III, the first level LV1 may be a level corresponding to an upper surface, and the second level LV2 may be a level having a maximum width and may be a bow level. The trench T may have a greater width at the second level LV2 than at the first level LV1. At the second level LV2, the first portion TA may have a first width W2A greater than the first width W1A, and the second portion TB may have a second width W2B greater than the second width W1B.

Subsequently, a buffer layer 73 may be formed in the trench T. The buffer layer 73 may be a kind of sacrificial layer, and may include oxide. The buffer layer 73 may have a shape transferred from the trench T. In a plan view, the buffer layer 73 may have a line shape or an irregular shape. In a cross section, the buffer layer 73 may have a bow shape.

The buffer layer 73 may be formed by a deposition method. In a process of depositing a buffer material in the trench T, the trench T may be sealed before the buffer material is completely filled in the trench T, and a void V may be induced. The void V may be an empty space in which the buffer material is not deposited, and may be filled with air.

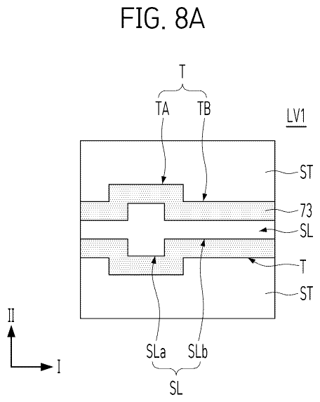

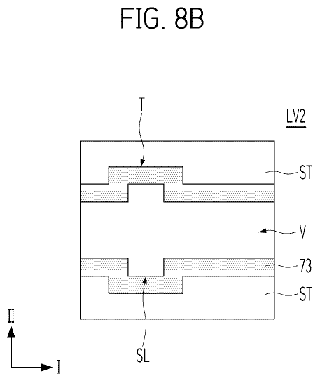

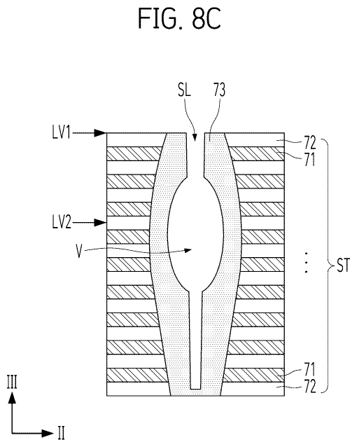

Referring to FIGS. 8A to 8C, a slit SL may be formed in the buffer layer 73. In a plan view, the slit SL may extend in the first direction I and/or the second direction II along the buffer layer 73. The slit SL may have a shape similar to that of the trench T. When the trench T has the line shape, the slit SL may also have a line shape. When the trench T has the irregular shape, the slit SL may also have an irregular shape. When the trench T and the slit SL each have the irregular shape, a first portion SLa of the slit SL may be located to correspond to the first portion TA of the trench T, and a second portion SLb of the slit SL may be located to correspond to the second portion TB of the trench T.

As an example, the slit SL may be partially formed in the buffer layer 73. The slit SL may be formed only in a portion where a crack is likely to occur, such as a boundary between adjacent memory blocks or a boundary between adjacent memory planes. As an example, the slit SL may be entirely formed in the buffer layer 73. The slit SL may be formed in a closed curve shape along an edge of a chip.

In a cross section, the slit SL may extend in the third direction III along the buffer layer 73. The slit SL may be formed at a depth at which it does not completely penetrate through the buffer layer, and a bottom surface of the slit SL may be located at a higher level than a lower surface of the buffer layer 73. The slit SL may be connected to the void V. A material layer might not be filled inside the slit SL and the void V, and an air gap may exist in the slit SL and the void V.

Subsequently, a crack may be generated and propagate due to stress induced in a manufacturing process. As an example, the stress and the crack may be induced by an oxidation process. A crack may be generated at an interface between a stack and an interlayer insulating layer, and may propagate in one direction along the interface to reach the buffer layer 73. The crack that has reached the buffer layer 73 may come into contact with an air gap, and because the air gap is an empty space in which a material transmitting the crack does not exist, the propagation of the crack may be stopped. As an example, an air gap may exist in the buffer layer 73 extending along the first direction I, and the crack propagating along the second direction II may be stopped by the air gap.

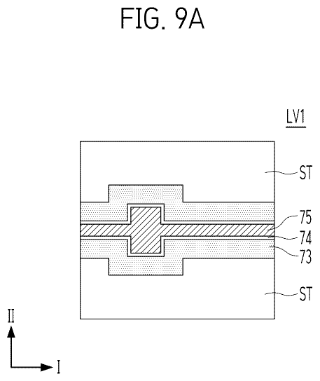

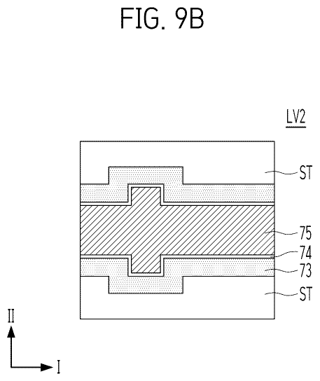

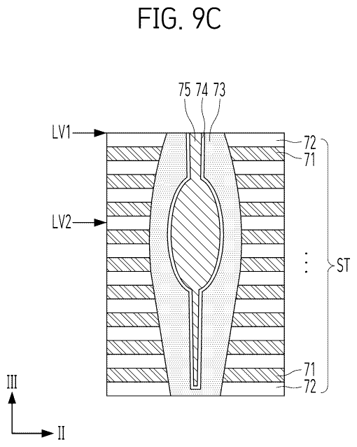

Referring to FIGS. 9A to 9C, an insulating spacer 74 may be formed in the slit SL and the void V. The insulating spacer 74 may include oxide. Subsequently, a conductive layer 75 may be formed on the insulating spacer 74. The conductive layer 75 may be used to form a source contact plug, and may include a polysilicon layer. The slit SL and the void V may be filled by the conductive layer 75.

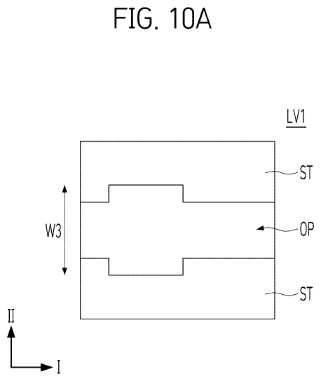

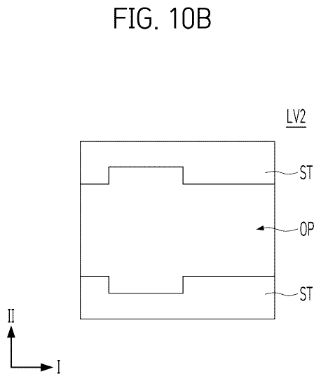

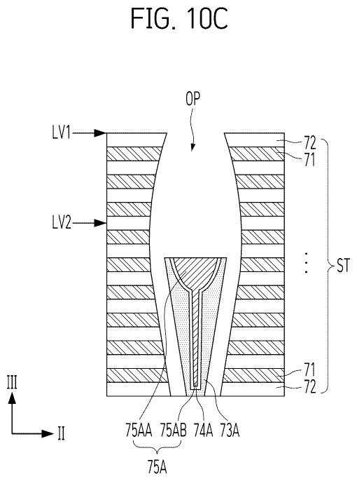

Referring to FIGS. 10A to 10C, an opening OP may be formed by etching the buffer layer 73, the insulating spacer 74, and the conductive layer 75. The opening OP may be formed by reopening a portion of the trench T that has been previously formed. Portions of the buffer layer 73, the insulating spacer 74, and the conductive layer 75 may be etched to remain a buffer layer 73A, an insulating spacer 74A, and a conductive layer 75A, respectively. The remaining conductive layer 75A may include a first portion 75AA including a curved surface and a second portion 75AB having a smaller width than the first portion 75AA. The first portion 75AA may be a portion filling the void V, and the second portion 75AB may be a portion filling the slit SL.

Etch rates of the buffer layer 73A, the insulating spacer 74A, and the conductive layer 75A may be different from each other. As an example, an etch rate of the buffer layer 73A may be greater than an etch rate of the conductive layer 75A. Shapes of the remaining buffer layer 73A, the insulating spacer 74A, and the conductive layer 75A and a shape of the opening OP may be changed depending on a difference in the etch rate.

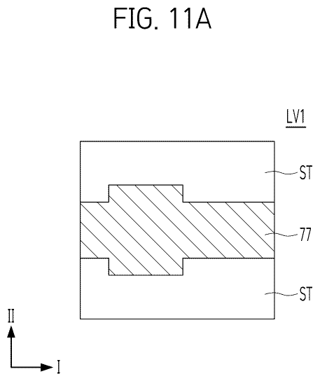

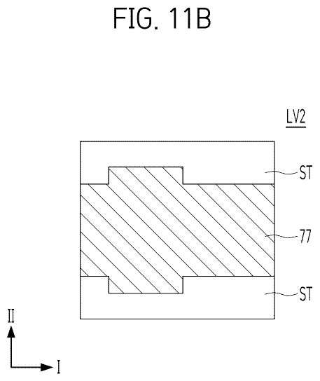

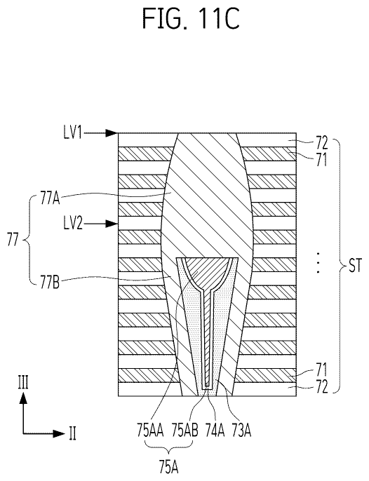

Referring to FIGS. 11A to 11C, a conductive line 77 may be formed in the opening OP. As an example, the conductive line 77 may be a detection line of a crack detection circuit, and may include metal such as tungsten (W), copper (Cu), or aluminum (Al). The conductive line 77 may include a first portion 77A located above the buffer layer 73A, the insulating spacer 74A, and the conductive layer 75A and a second portion 77B surrounding sidewalls of the buffer layer 73A. When the opening OP has an irregular shape, a probability that a void having a line shape will be formed inside the conductive line 77 may be reduced, and the induction of a crack due to thermal stress may be reduced.

According to the method described above, even though the crack is induced in the manufacturing process of the semiconductor device, the propagation of the crack may be stopped through the air gap in the slit SL and the void V.

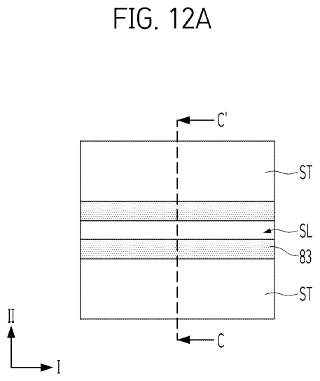

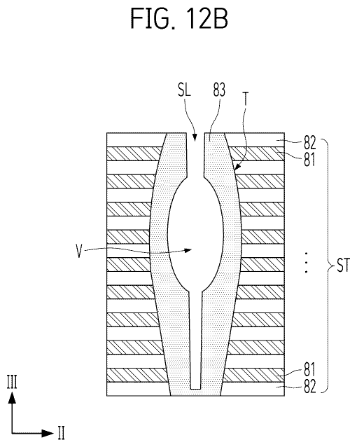

FIGS. 12A, 13A, and 14A and FIGS. 12B, 13B, and 14B are diagrams for describing a method of manufacturing a semiconductor device in accordance with an embodiment. FIGS. 12B, 13B, and 14B are cross-sectional views taken along lines C-C′ of FIGS. 12A, 13A, and 14A, respectively.

Referring to FIGS. 12A and 12B, a stack ST including first material layers 81 and second material layers 82 that are alternately stacked may be formed. Subsequently, a trench T may be formed in the stack ST, and a buffer layer 83 including a void V may be formed in the trench T. Subsequently, a slit SL may be formed in the buffer layer 83. The slit SL may be connected to the void V.

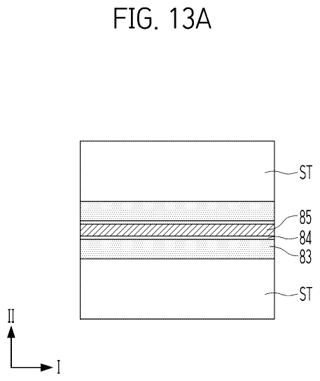

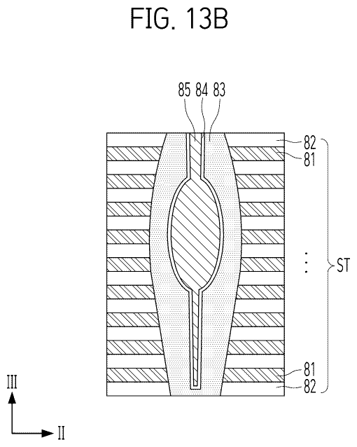

Referring to FIGS. 13A and 13B, a second stop layer 84 may be formed in the slit SL and the void V. The second stop layer 84 may include a material having a higher elastic modulus (Young's modulus) than the buffer layer 83, and may include nitride. Subsequently, a first stop layer 85 may be formed on the second stop layer 84. The first stop layer 85 may be a conductive layer for forming a source layer, and may include a material having a higher elastic modulus (Young's modulus) than the buffer layer 83 and the second stop layer 84. As an example, the first stop layer 85 may include a conductive material such as polysilicon.

Subsequently, a crack may be generated and propagate due to stress induced in a manufacturing process. As an example, the stress and the crack may be induced by an oxidation process. A crack may be generated at an interface between a stack and an interlayer insulating layer, and may propagate in one direction along the interface to reach the buffer layer 83. The crack that has reached the buffer layer 83 may come into contact with the second stop layer 84, and the propagation of the crack may be stopped by the second stop layer 84 and the first stop layer 85.

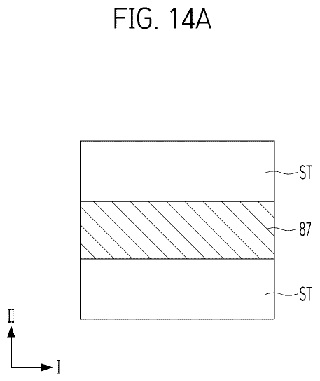

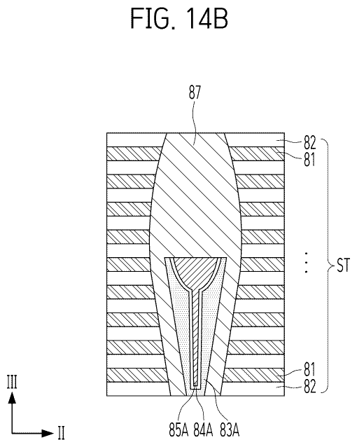

Referring to FIGS. 14A and 14B, an opening OP may be formed by etching the buffer layer 83, the second stop layer 84, and the first stop layer 85. A buffer layer 83A, a second stop layer 84A and a first stop layer 85A may remain. Subsequently, a conductive line 87 may be formed in the opening OP. The conductive line 87 may surround the buffer layer 83A, the second stop layer 84A, and the first stop layer 85A. The conductive line 87 may include metal such as tungsten (W).

According to the method described above, even though the crack is induced by the oxidation process or the like in the manufacturing process of the semiconductor device, the propagation of the crack may be stopped by the second stop layer 84 and the first stop layer 85.

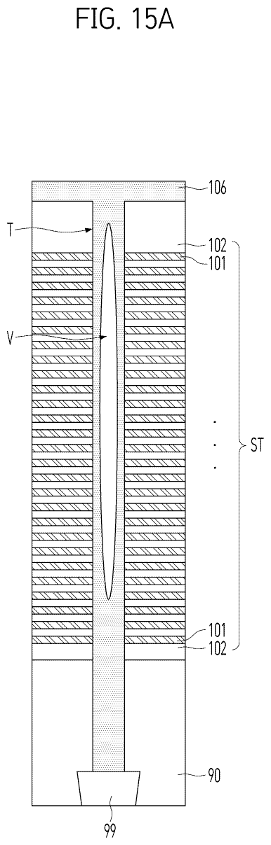

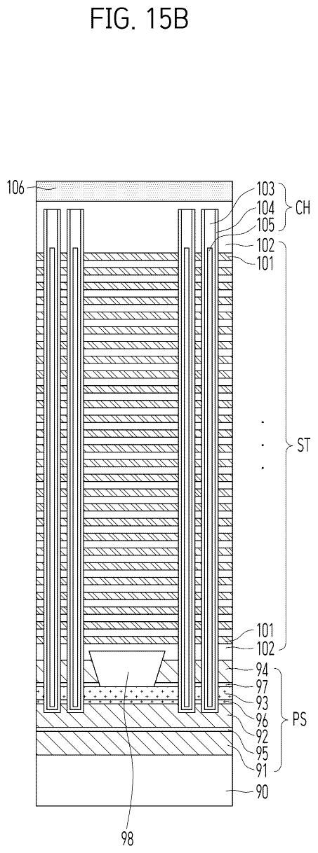

FIGS. 15A, 16A, 17A, 18A, 19A, 20A, 21A, 22A, 23A, 24A, and 25A and FIGS. 15B, 16B, 17B, 18B, 19B, 20B, 21B, 22B, 23B, 24B, and 25B are diagrams for describing a method of manufacturing a semiconductor device in accordance with an embodiment of the present disclosure. FIGS. 15A, 16A, 17A, 18A, 19A, 20A, 21A, 22A, 23A, 24A, and 25A are cross-sectional views of a chip guard region CGR, and FIGS. 15B, 16B, 17B, 18B, 19B, 20B, 21B, 22B, 23B, 24B, and 25B are cross-sectional views of a chip region CHR.

Referring to FIGS. 15A and 15B, a preliminary source structure PS including a source sacrificial layer 93 may be formed on an interlayer insulating layer 90 including a wiring line 99. The wiring line 99 may be a portion of a crack detection circuit. The preliminary source structure PS may be located in the chip region CHR, and may include a first source layer 92, a second source layer 94, and the source sacrificial layer 93 located between the first source layer 92 and the second source layer 94. The preliminary source structure PS may further include a first protective layer 96 located between the first source layer 92 and the source sacrificial layer 93 and a second protective layer 97 located between the source sacrificial layer 93 and the second source layer 94. The preliminary source structure PS may further include a sub-source layer 91 and an insulating layer 95 located between the sub-source layer 91 and the first source layer 92. As an example, the first source layer 92, the second source layer 94, and the sub-source layer 91 may each include polysilicon, and the first protective layer 96, the second protective layer 97, and the insulating layer 95 may each include oxide.

Subsequently, a stack ST may be formed in the chip region CHR and the chip guard region CGR. The stack ST may include first material layers 101 and second material layers 102 that are alternately stacked. The first material layers 101 may each include a material having a high etching selectivity with respect to the second material layers 102. As an example, the first material layers 101 may each include a sacrificial material such as nitride or a conductive material such as polysilicon or metal. The second insulating layers 102 may each include an insulating material such as oxide.

For reference, before the stack ST is formed, an etch stop pattern 98 may be formed on the preliminary source structure PS. The etch stop pattern 98 may be a pattern that is to be used as an etch stop layer in a subsequent process of forming a slit. The etch stop pattern 98 may include a material having a high etching selectivity with respect to the first and second material layers 101 and 102, and may include tungsten.

Subsequently, a channel structure CH may be formed in the chip region CHR. The channel structure CH may extend into the preliminary source structure PS through the stack ST. As an example, the channel structure CH may penetrate through the second source layer 94, the second protective layer 97, the source sacrificial layer 93, and the first protective layer 96, and may extend into the first source layer 92. The channel structure CH may include a channel layer 103, a memory layer 104 surrounding the channel layer 103, and an insulating core 105 located in the channel layer 103. The memory layer 104 may include a blocking layer, a data storage layer, and a tunneling layer. Subsequently, a second material layer 102 may be additionally formed on the stack ST to cover an upper surface of the channel structure CH.

Subsequently, a trench T surrounding the chip region CHR may be formed in the chip guard region CGR. The trench T may extend through the stack ST, and may expose the wiring line 99. As an example, the trench T may have sidewalls with a line shape or an irregular shape. Subsequently, a buffer layer 106 including a void V may be formed in the trench T. The buffer layer 106 may extend along an upper surface of the stack ST. The buffer layer 106 may include oxide.

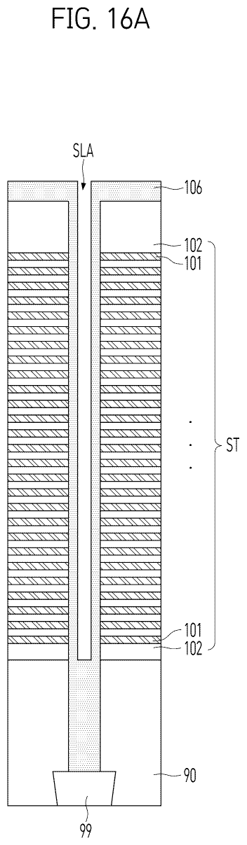

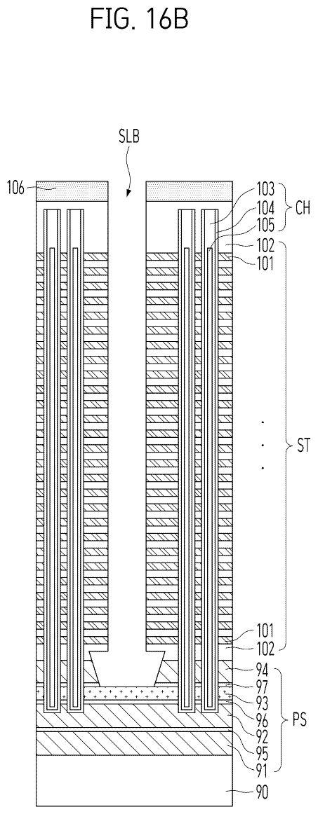

Referring to FIGS. 16A and 16B, a slit SLA located in the chip guard region CGR and a slit SLB located in the chip region CHR may be formed. When the trench T has the irregular shape, the slit SLA may also have an irregular shape corresponding to the trench T. The slit SLA and the slit SLB may be simultaneously formed. The slit SLA may be formed by etching the buffer layer 106, and may be connected to the void V. A bottom surface of the slit SLA may be located at a higher level than a bottom surface of the buffer layer 106, and the wiring line 99 may not be exposed. The slit SLA may have a smaller width than the trench T, and the stack ST may not be exposed. The slit SLB may be located between the channel structures CH, and may extend through the stack ST to expose the etch stop pattern 98. Subsequently, the etch stop pattern 98 may be removed through the slit SLB.

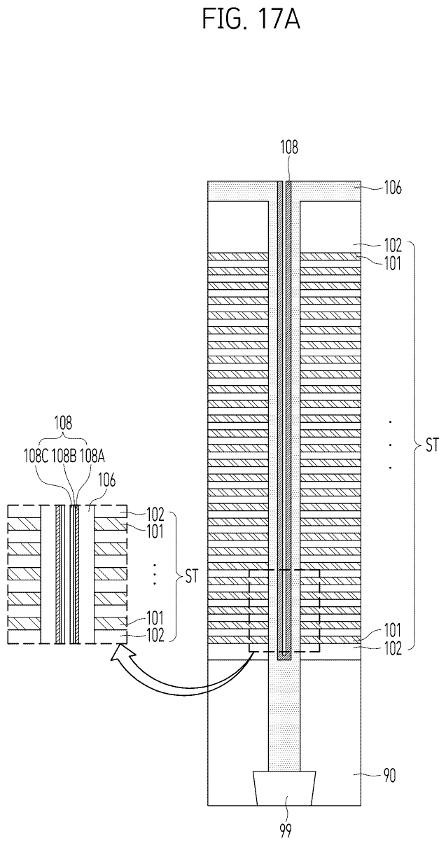

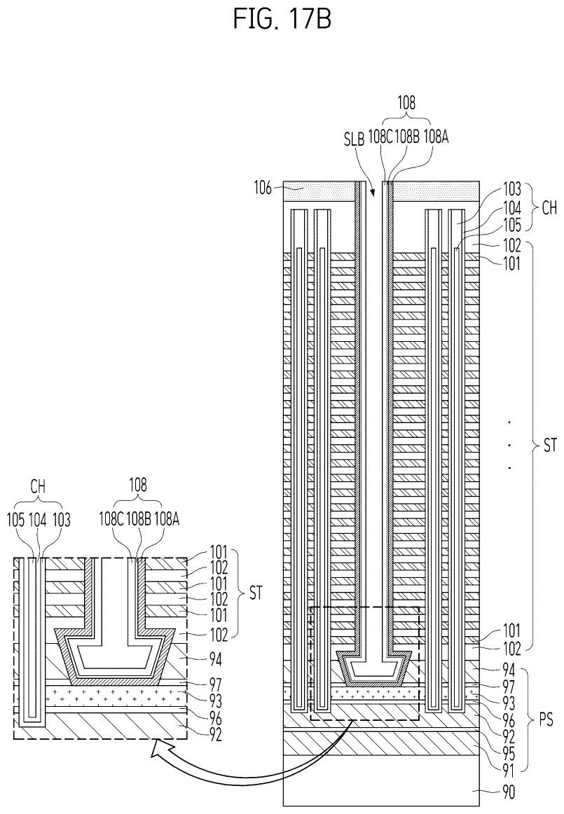

Referring to FIGS. 17A and 17B, liners 108 may be formed in the slits SLA and SLB. The liner(s) 108 may be formed along inner surfaces of the slits SLA and SLB, and central regions of the slits SLA and SLB may be opened.

The liner 108 may be used to protect the stack ST in a subsequent process of etching the memory layer 104. The liner 108 may be composed of a single layer or a multilayer layer. As an example, the liner 108 may include a first nitride layer 108A, an oxide layer 108B and a second nitride layer 108C. The first nitride layer 108A may be formed, the oxide layer 108B may be formed on the first nitride layer 108A, and the second nitride layer 108C may be formed on the oxide layer 108B.

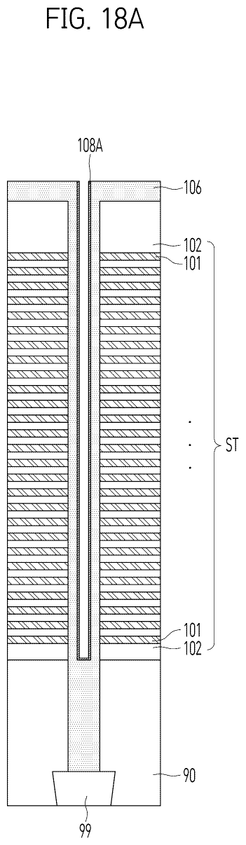

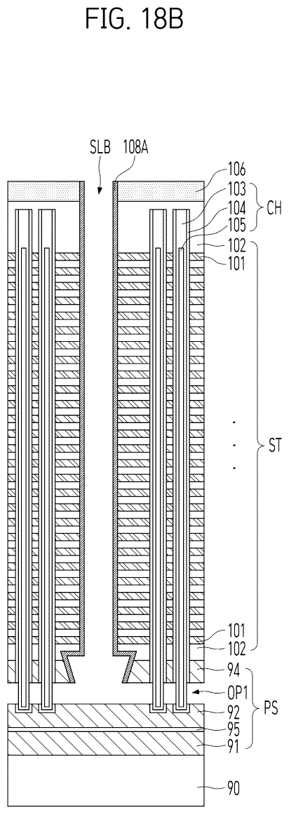

Referring to FIGS. 18A and 18B, a first opening OP1 may be formed by removing the source sacrificial layer 93 through the slit SLB. Subsequently, the memory layer 104 may be etched so that the channel layer 103 is exposed. As an example, the blocking layer, the data storage layer, and the tunneling layer may be etched using a dry cleaning process. In this process, the first protective layer 96 and the second protective layer 97 may be etched, and the first source layer 92 and the second source layer 94 may be exposed in the first opening OP1. In addition, the second nitride layers 108C and the oxide layers 108B in the slits SLA and SLB may be etched, and the first nitride layers 108A in the slits SLA and SLB may be exposed. Through this, the second nitride layers 108C and the oxide layers 108B in the slits SLA and SLB may be removed, and the first nitride layers 108A in the slits SLA and SLB may remain.

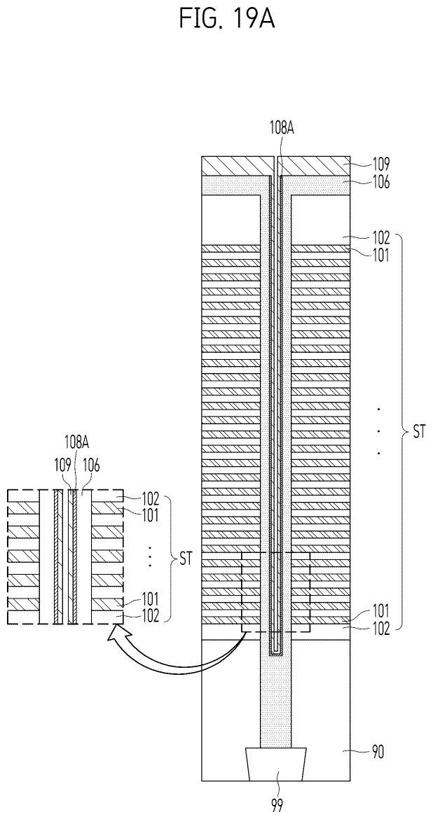

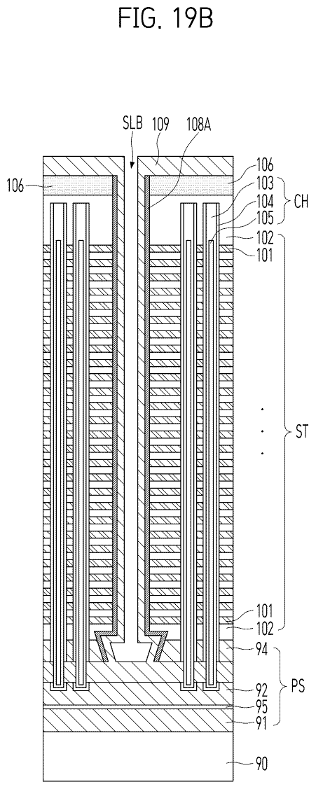

Referring to FIGS. 19A and 19B, a conductive layer 109 may be formed. The conductive layer 109 may fill the first opening OP1, and may extend along the slit SLB. The conductive layer 109 may extend along the slit SLA, and may also be formed on the upper surface of the stack ST. The slit SLA may not be completely filled with the conductive layer 109.

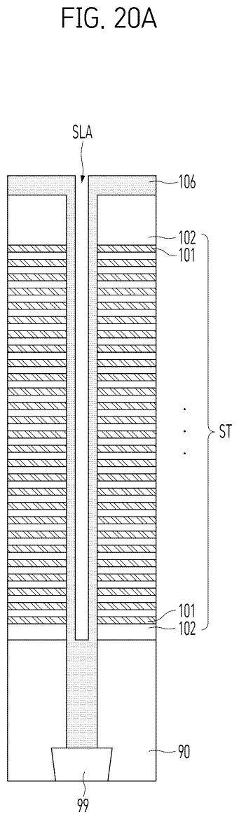

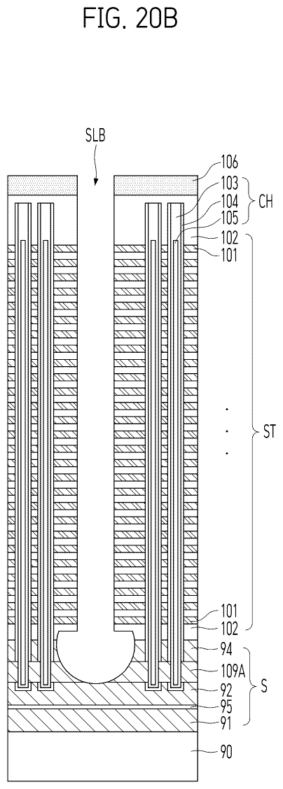

Referring to FIGS. 20A and 20B, a third source layer 109A may be formed in the first opening OP1 by etching the conductive layer 109. As an example, the conductive layer 109 may be etched using a wet etching process. Through this, a source structure S including the first source layer 92, the second source layer 94, the third source layer 109A, the sub-source layer 91, and the insulating layer 95 may be formed.

In a process of etching the conductive layer 109, the conductive layer 109 in the slit SLA may be removed, and the buffer layer 106 may be exposed. When the slit SLA has an irregular shape, an inflow passage of a wet etching chemical may be secured, and the conductive layer 109 may not remain in the slit SLA. The inside of the buffer layer 106 may have an empty state, and an air gap may be located inside the buffer layer 106. Subsequently, the first nitride layers 108A in the slits SLA and SLB may be removed.

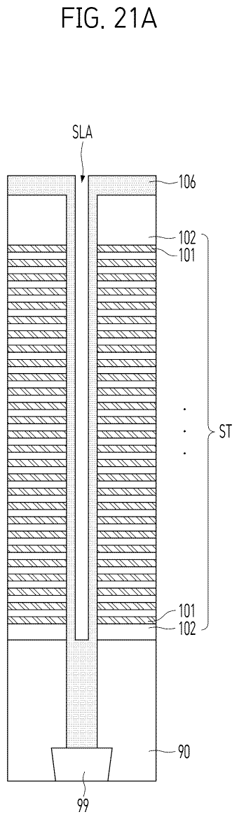

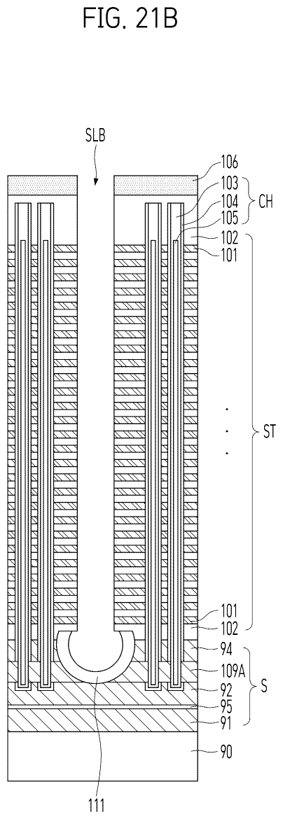

Referring to FIGS. 21A and 21B, a protective pattern 111 may be formed using an oxidation process. Surfaces of the first source layer 92, the second source layer 94, and the third source layer 109A exposed through the slit SLB may be oxidized, and the protective pattern 111 may be formed.

Stress may be induced by the oxidation process, and a crack may occur. The crack may occur at a boundary between adjacent memory blocks, a boundary between adjacent memory planes, or an edge of a chip. As an example, a crack may occur at an interface between the stack ST and the interlayer insulating layer, and may propagate in one direction along the interface. When the crack reaches the buffer layer 106 of the chip guard region CGR, the propagation of the crack may be stopped by the air gap.

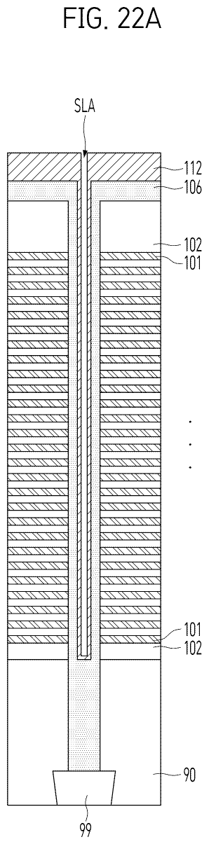

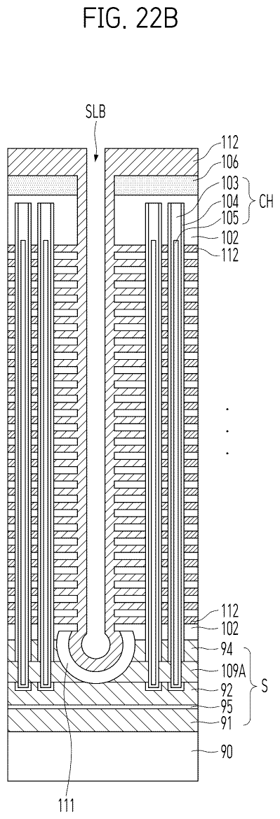

Referring to FIGS. 22A and 22B, the first material layers 101 may be removed, and a conductive layer 112 may then be formed. Because the first material layers 101 are exposed through the slit SLB in the chip region CHR, the first material layers 101 may be selectively etched. When the first material layers 101 are etched, the source structure S may be protected by the protective pattern 111. The conductive layer 112 may be filled in regions where the first material layers 101 are etched, and may extend along an inner surface of the slit SLB. Because the first material layers 101 are covered by the buffer layer 106 in the chip guard region CHR, the first material layers 101 are not exposed through the slit SLA. The first material layers 101 are maintained as they are, and a conductive layer 112 may be formed in the slit SLA.

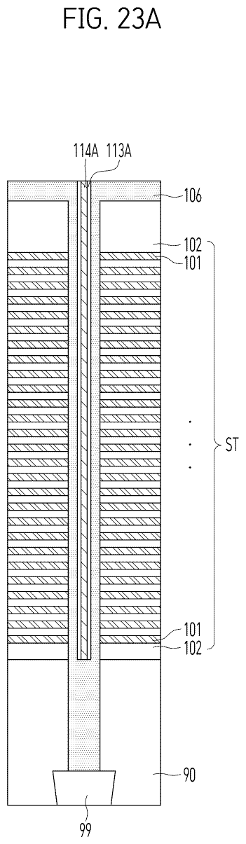

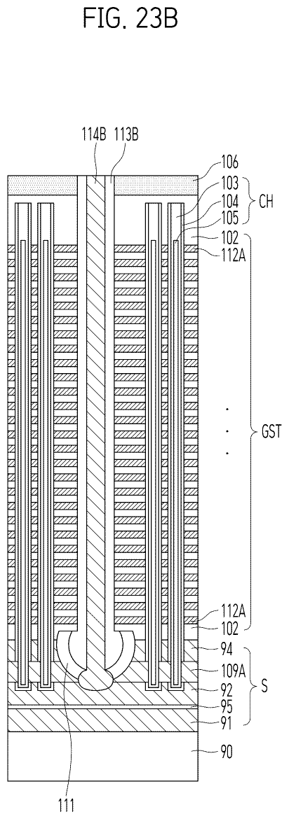

Referring to FIGS. 23A and 23B, gate lines 112A may be formed by etching the conductive layer 112. When the slit SLA has the irregular shape, an inflow passage of a wet etching chemical may be secured, and the conductive layer 112 may not remain in the slit SLA. Through this, a gate structure GST including the second material layers 102 and the gate lines 112A that are alternately stacked may be formed. Because the first material layers 101 of the chip guard region CGR are not replaced with the gate lines 112A, the stack ST may remain in the chip guard region CGR, and the remaining stack ST may be a dummy structure.

Subsequently, an insulating spacer 113A and a conductive layer 114A may be formed in the chip guard region CGR. An insulating spacer 113B and a source contact plug 114B may be formed in the chip region CHR. When the insulating spacer 113A is formed, the insulating spacer 113B may be formed. When the conductive layer 114A is formed, the source contact plug 114B may be formed. The insulating spacers 113A and 113B may each include oxide, and the conductive layer 114A and the source contact plug 114B may each include polysilicon.

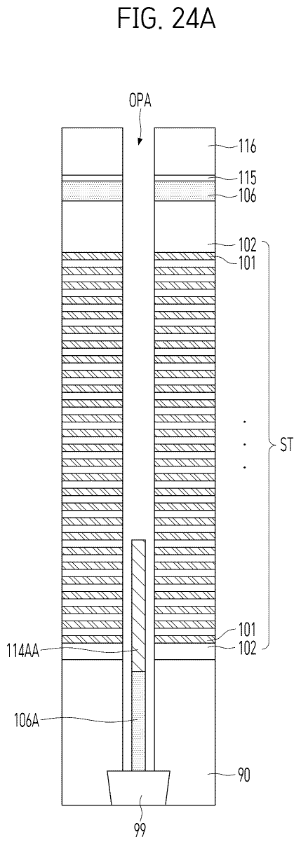

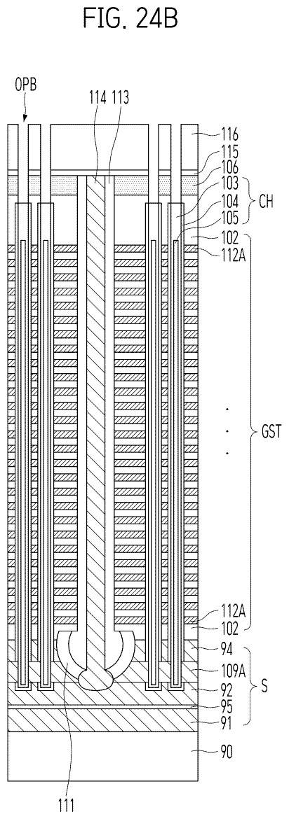

Referring to FIGS. 24A and 24B, a sealing layer 115 may be formed in the chip guard region CGR and the chip region CHR. The sealing layer 115 may be used to cover an upper surface of the source contact plug of the chip region CHR. An interlayer insulating layer 116 may be formed on the sealing layer 115.

Subsequently, an opening OPA may be formed by etching the conductive layer 114A, the insulating spacer 113A, and the buffer layer 106 of the chip guard region CGR. Etch rates of the conductive layer 114A, the insulating spacer 113A, and the buffer layer 106 may be different from each other. Etch rates of the insulating spacer 113A and the buffer layer 106 may be greater than an etch rate of the conductive layer 114A, and a conductive layer 114AA and a buffer layer 106A may remain.

Openings OPB exposing the channel structures CH may be formed by etching the interlayer insulating layer 116 and the buffer layer 106 of the chip region CHR. When the opening OPA is formed, the opening OPB may be formed.

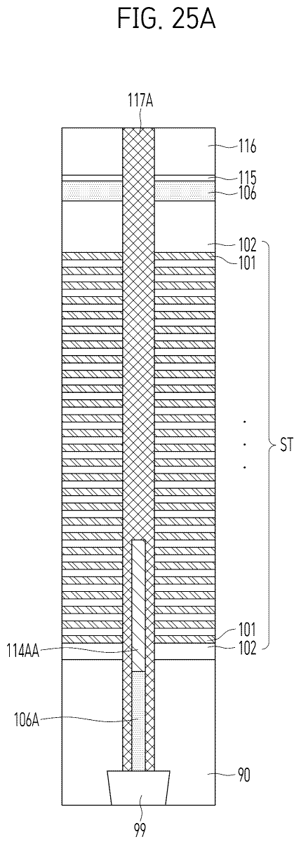

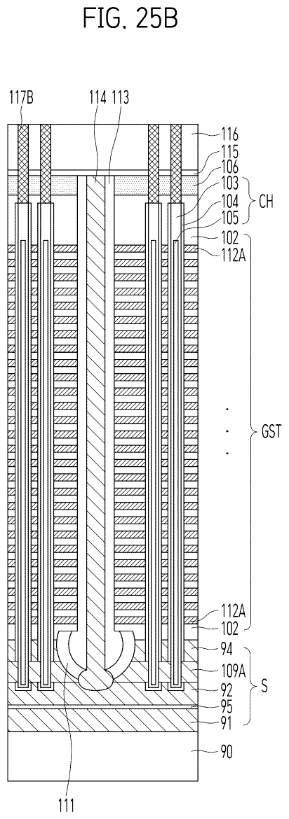

Referring to FIGS. 25A and 25B, a conductive layer may be formed in the openings OPA and OPB. The conductive layer may include a metal such as tungsten. Through this, a conductive line 117A may be formed in the chip guard region CGR. The conductive line 117A may be a portion of the crack detection circuit. A contact plug 117B may be formed in the chip region CHR. When the conductive line 117A is formed, the contact plug 117B may be formed.

According to the method described above, even in instances in which cracks occur due to the oxidation process or the like, the propagation of the crack may be stopped by the air gap in the slit SLA. The air gap may be used as a stop layer. The contact plug of the chip region CHR and the conductive line of the chip guard region CGR may be simultaneously formed.

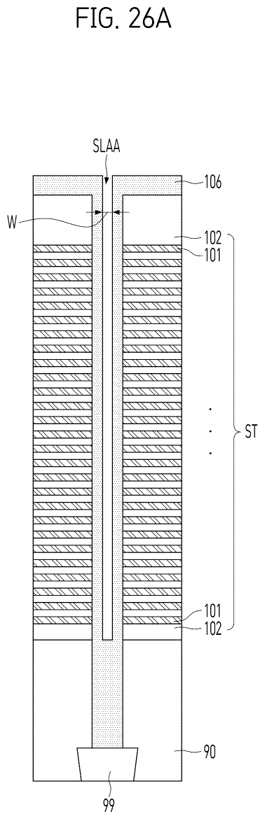

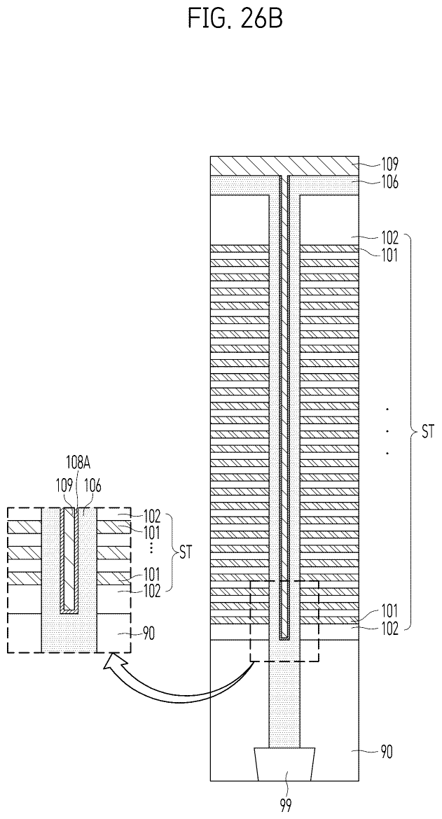

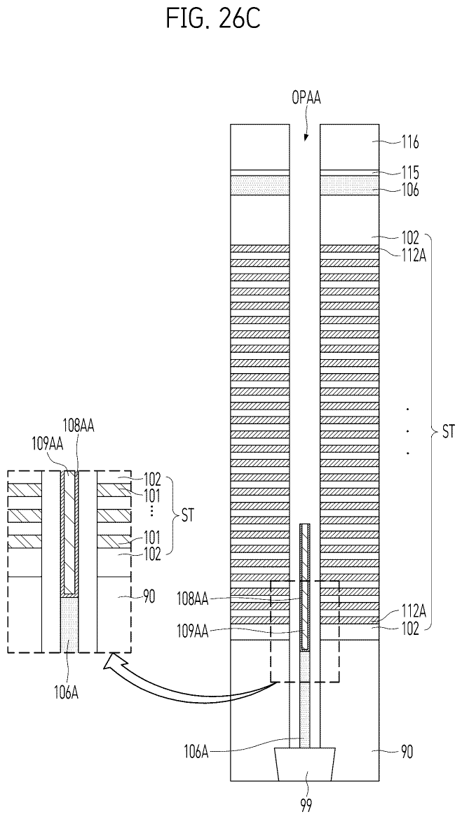

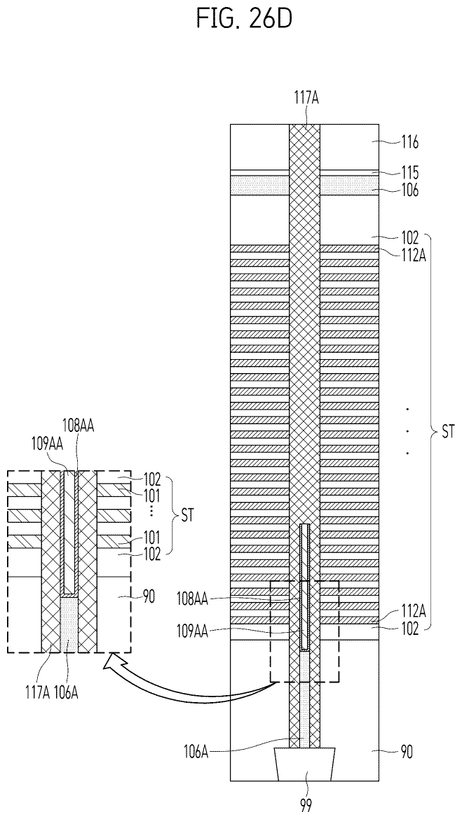

FIGS. 26A to 26D are diagrams for describing a method of manufacturing a semiconductor device in accordance with an embodiment, and illustrate a chip guard region CGR. Hereinafter, the content overlapping with the previously described content may be omitted.

Referring to FIG. 26A, a slit SLAA may be formed by etching a buffer layer 106. FIG. 26A may correspond to the process step described above with reference to FIGS. 16A and 16B. The slit SLAA may have a smaller width than the slit SLA of FIG. 16A. A bottom surface of the slit SLAA may be located at a higher level than a bottom surface of the buffer layer 106, and the wiring line 99 may not be exposed.

Subsequently, as described above with reference to FIGS. 17A and 17B, a liner 108 including a first nitride layer 108A, an oxide layer 108B, and a second nitride layer 108C may be formed in the slit SLAA. Subsequently, as described above with reference to FIGS. 18A and 18B, the second nitride layer 108C and the oxide layer 108B in the slit SLAA may be etched.

Referring to FIG. 26B, a conductive layer 109 may be formed on the first nitride layer 108A. FIG. 26B may correspond to the process step described above with reference to FIGS. 19A and 19B. Because the slit SLAA has the smaller width than the slit SLA, the conductive layer 109 may be completely filled in the slit SLAA. The conductive layer 109 may include polysilicon.

Subsequently, as described above with reference to FIGS. 20A and 20B, the conductive layer 109 may be etched. Because the slit SLAA is in a state in which it is completely filled with the conductive layer 109, the conductive layer 109 inside the slit SLAA may not be etched.

Subsequently, as described above with reference to FIGS. 21A and 21B, an oxidation process may be performed. Stress may be induced by the oxidation process, and a crack may occur. The crack may occur at a boundary between adjacent memory blocks, a boundary between adjacent memory planes, or an edge of a chip. As an example, a crack may occur at an interface between the stack ST and the interlayer insulating layer, and may propagate in one direction along the interface. The first nitride layer 108A and the conductive layer 109 may each include a material having a higher elastic modulus (Young's modulus) than the buffer layer 106, and may be used as stop layers. The conductive layer 109 may be a first stop layer, and the first nitride layer 108A may be a second stop layer. When the crack reaches the buffer layer 106 of the chip guard region CGR, the propagation of the crack may be stopped by the first nitride layer 108A and the conductive layer 109.

Subsequently, as described with reference to FIGS. 22A, 22B, 23A, and 23B, a conductive layer 112 may be formed and etched. Because the conductive layer 109 is in a state in which it is filled in the slit SLAA, the conductive layer 112 may be formed above the stack ST and then removed. Subsequently, an insulating spacer 113A and a conductive layer 114A may be formed above the stack ST and then removed.

Referring to FIG. 26C, a sealing layer 115 and an interlayer insulating layer 116 may be formed on the buffer layer 106, and an opening OPAA may be formed. FIG. 26C may correspond to the process step described above with reference to FIGS. 24A and 24B. The opening OPAA may be formed by etching the conductive layer 109, the first nitride layer 108A, and the buffer layer 106. Etch rates of the conductive layer 109, the first nitride layer 108A, and the buffer layer 106 may be different from each other. An etch rate of the buffer layer 106 may be greater than etch rates of the conductive layer 109 and the first nitride layer 108A, and a conductive layer 109AA and a first nitride layer 108AA may remain.

Referring to FIG. 26D, a conductive line 117A may be formed in the opening OPAA. FIG. 26D may correspond to the process step described above with reference to FIGS. 25A and 25B. The conductive line 117A may include metal such as tungsten.

According to the method described above, even in instances in which a crack occurs due to the oxidation process or the like, the propagation of the crack may be stopped by the first nitride layer 108A and the conductive layer 109 in the slit SLAA. The first nitride layer 108A and the conductive layer 109 may be used as stop layers.

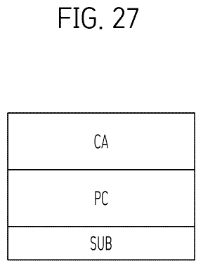

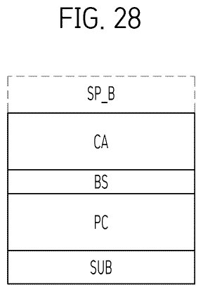

The structure and the manufacturing method according to the above-described embodiments may be applied to semiconductor devices of various structures. FIGS. 27 and 28 illustrate a schematic configuration of a semiconductor device to which the above-described embodiments are applicable.

FIG. 27 is a configuration diagram of a semiconductor device according to an embodiment of the present disclosure.

Referring to FIG. 27, the semiconductor device may include a substrate SUB, a peripheral circuit PC, and a memory cell array CA. Here, the peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor. Here, the group IV semiconductor may include single crystal silicon (Si), polycrystalline silicon, germanium (Ge), or silicon germanium (SiGe). The group III-V compound semiconductor may include gallium arsenide (GaAs), gallium nitride (GaN), gallium phosphide (GaP), gallium arsenide phosphide (GaAsP), gallium indium arsenide phosphide (GaInAsP), aluminum arsenide (AlAs), aluminum gallium (AlGa), indium phosphide (InP), indium antimonide (InSb), or indium gallium arsenide (InGaAs). The group II-VI compound semiconductor may include zinc sulfide (ZnS), zinc oxide (ZnO), or cadmium sulfide (CdS).

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an N-channel a Metal-Oxide-Semiconductor (NMOS) transistor, a P-channel Metal-Oxide-Semiconductor (PMOS) transistor, a resistor, a capacitor, and the like. The peripheral circuit PC may further include an interconnection structure. The interconnection structure may be used as a path for transferring an operation voltage, and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 28 is a configuration diagram of a semiconductor device according to an embodiment of the present disclosure.

Referring to FIG. 28, the semiconductor device may include a substrate SUB, a peripheral circuit PC, a bonding structure BS, and a memory cell array CA. Here, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

For reference, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, contact plugs, lines, and the like formed on different wafers may be electrically connected without a separate bonding pad.

Other configurations may be equal or similar to those described above with reference to FIG. 27.

In further embodiments, the semiconductor device may have a structure in which the embodiments described above with reference to FIGS. 27 and 28 are combined or may have a partially modified structure. In the embodiment described with reference to FIGS. 27 and 28, positions of the memory cell array CA and the peripheral circuit PC may be changed. At least one memory cell array CA and/or at least one peripheral circuit PC may be additionally bonded to the embodiment described with reference to FIGS. 27 and 28. In an embodiment, a portion of the peripheral circuitry PC may be disposed in the memory cell array CA.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A method of manufacturing a semiconductor device, the method comprising:
forming a stack in a chip region and a chip guard region surrounding the chip region, the stack including alternately stacked first material layers and second material layers;
forming a trench in the chip guard region of the stack, the trench surrounding the chip region;
forming a buffer layer in the trench, the buffer layer including a void; and
forming a slit in the buffer layer, the slit being connected to the void to define an air gap within the void and the slit,
wherein the air gap is configured to stop propagation of a crack from the chip region toward the chip guard region.

2. The method of claim 1, further comprising:
forming a polysilicon layer in the void and the slit; and
removing a portion of the polysilicon layer.

3. The method of claim 2, further comprising forming a source layer in the chip region when the polysilicon layer is formed.

4. The method of claim 1, further comprising
forming a metal layer in the void and the slit; and
removing a portion of the metal layer.

5. The method of claim 4, further comprising forming gate lines in the chip region when the metal layer is formed.

6. The method of claim 1, further comprising
forming an insulating spacer in the void and the slit; and
forming a polysilicon layer on the insulating spacer.

7. The method of claim 6, further comprising forming a source contact plug in the chip region when the polysilicon layer is formed.

8. The method of claim 6, further comprising
forming an opening by etching the buffer layer, the insulating spacer, and the polysilicon layer; and
forming a conductive line in the opening.

9. The method of claim 8, further comprising forming a contact plug in the chip region when the conductive line is formed.

10. The method of claim 8, wherein the forming of the opening includes forming the opening to expose sidewalls of the polysilicon layer.

11. The method of claim 8, wherein in the forming of the opening, an etch rate of the buffer layer is greater than an etch rate of the polysilicon layer.

12. The method of claim 1, wherein the crack is induced by an oxidation process.

13. A method of manufacturing a semiconductor device, the method comprising:
forming a stack in a chip region and a chip guard region surrounding the chip region, the stack including alternately stacked first material layers and second material layers;
forming a trench in the chip guard region of the stack, the trench surrounding the chip region;
forming a buffer layer in the trench, the buffer layer including a void;
forming a slit in the buffer layer, the slit being connected to the void; and
forming a stop layer in the void and the slit, wherein the stop layer is configured to stop propagation of a crack from the chip region toward the chip guard region.

14. The method of claim 13, wherein the forming of the stop layer comprises:
forming a nitride layer in the void and the slit; and
forming a polysilicon layer on the nitride layer.

15. The method of claim 14, further comprising forming a source layer in the chip region when the polysilicon layer is formed.

16. The method of claim 14, further comprising:
forming an opening by etching the polysilicon layer, the nitride layer, and the buffer layer; and
forming a conductive line in the opening.

17. The method of claim 16, further comprising forming a contact plug in the chip region when the conductive line is formed.

18. The method of claim 16, wherein the forming of the opening includes forming the opening to expose the nitride layer.

19. The method of claim 16, wherein in the forming of the opening, an etch rate of the buffer layer is greater than etch rates of the nitride layer and the polysilicon layer.

20. The method of claim 13, wherein the crack is induced by an oxidation process.
